(19) United States
(12) Patent Application Publication
(10) Pub. No.: US 2014/0028354 A1
(43) Pub. Date: Jan. 30, 2014

(54) ZERO-CROSSING DETECTION METHOD AND CIRCUIT

(71) Applicant: Huawei Technologies Co., Ltd., Shenzhen (CN)

(72) Inventors: GUOLIANG YAO, Beijing (CN); Zhenyu Ma, Beijing (CN)

(73) Assignee: Huawei Technologies Co., Ltd., Shenzhen (CN)

(21) Appl. No.: 13/865,562

(22) Filed: Apr. 18, 2013

(30) Foreign Application Priority Data
Apr. 18, 2012 (CN) 201210114625.1

(51) Int. Cl. H03K 5/1536

(52) U.S. Cl. CPC H03K 5/1536
USPC 327/79

(57) ABSTRACT

Embodiments of the present invention disclose a zero-crossing detection method and circuit. The zero-crossing detection method includes: detecting a time point t0 when a mains voltage jumps from a low electrical level to a high electrical level and an adjacent time point t1 when the mains voltage jumps from a high electrical level to a low electrical level at a port of a detection end; and determining, according to the detected time points t0 and t1, a time point t when the mains voltage crosses zero.

### CROSS-REFERENCE TO RELATED APPLICATION

This application claims priority to Chinese Patent Application No. 201210114625.1, filed on Apr. 18, 2012, which is hereby incorporated by reference in its entirety.

### FIELD OF THE INVENTION

The present invention relates to the field of power line communication and control, and in particular, to a zero-crossing detection method and circuit.

### BACKGROUND OF THE INVENTION

In power line communication, synchronization control of the communication needs to be performed through a unified time point, and by detecting a time point when the mains crosses zero, unified time reference may be determined, so as to perform the synchronization control on the communication; therefore, zero-crossing detection of the mains becomes an indispensable part in the power line communication.

Currently, multiple zero-crossing detection circuit solutions exist. FIG. 1 shows a zero-crossing detection circuit in the prior art. In FIG. 1, a live line of a mains network is connected to a first pin of a bridge rectifier circuit D, and a zero line of the mains network is connected to a third pin of the bridge rectifier circuit D; a second pin of the bridge rectifier circuit D is connected to one input end of an optical coupler U1 through a resistor R1, and a fourth pin of the bridge rectifier circuit D is connected to the other input end of the optical coupler U1; one output end of the optical coupler U1 is connected to a power source VDD, and the other output end of the optical coupler U1 is connected to a base of a transistor Q1 through a resistor R2; and a collector of the transistor Q1 is connected to the base of the transistor Q1 through a resistor R3, and the collector of the transistor Q1 is connected to a detection port P1.0.

Through this circuit, full-bridge rectification is directly performed on the mains to generate a pulse direct current signal of 100 Hz. When the optical coupler U1 is conducted, the collector of the transistor Q1 shows a low electrical level, while when the optical coupler U1 is not conducted, the collector of the transistor Q1 shows a high electrical level, and the detection port P1.0 detects a high electrical level. Because the optical coupler U1 is not conducted when the mains crosses zero, a positive pulse signal of 100 Hz is eventually generated when the mains crosses zero, so as to implement the zero-crossing detection.

However, in the process of implementing the foregoing zero-crossing detection, the inventor finds that at least the following problem exists in the prior art: because a mains voltage remains higher than a conduction voltage of the optical coupler U1 for a long time, that is, the conduction time of the optical coupler U1 in the zero-crossing detection circuit as shown in FIG. 1 is rather long, the power consumption is very high.

### SUMMARY OF THE INVENTION

Embodiments of the present invention provide a zero-crossing detection method and a zero-crossing detection circuit, so as to lower the power consumption of a zero-crossing detection circuit in the prior art.

In order to achieve the foregoing objective, the embodiments of the present invention adopt the following technical solutions:

An embodiment of the present invention provides a zero-crossing detection method, which includes:

detecting a time point t0 when a mains voltage jumps from a low electrical level to a high electrical level and an adjacent time point t1 when the mains voltage jumps from a high electrical level to a low electrical level at a port of a detection end; and determining, according to the detected time points t0 and t1, a time point t when the mains voltage crosses zero.

In the zero-crossing detection method provided by the embodiment of the present invention, the time point when the mains voltage crosses zero is indirectly detected by detecting the time points t0 and t1 of two feature points when the mains voltage is approaching a peak value, and because a time period that the mains voltage is higher than the voltages at these two feature points when approaching the peak value is short, the zero-crossing detection method shortens the conduction time of a zero-crossing detection circuit, so that the power consumption is low.

An embodiment of the present invention further provides a zero-crossing detection circuit for implementing the foregoing zero-crossing detection method, which includes a live line and a zero line of the mains, where the live line and the zero line of the mains are connected to a rectifier circuit, the rectifier circuit is connected to an output circuit, and a current-limiting circuit is connected between the live line and the zero line of the mains and the rectifier circuit.

Through the zero-crossing detection circuit provided by the embodiment of the present invention, the current of the whole zero-crossing detection circuit is reduced to a great extent through a strong current-limiting function of the current-limiting circuit, so that the zero-crossing detection circuit is conducted when a mains voltage is approaching a peak value, the conduction time of the zero-crossing detection circuit is short and the power consumption is low.

### BRIEF DESCRIPTION OF THE DRAWINGS

FIG. 1 is a schematic circuit diagram of a specific implementation of a zero-crossing detection circuit in the prior art;

FIG. 2 is a schematic diagram of a zero-crossing detection method according to an embodiment of the present invention;

FIG. 3 is a principle diagram of a zero-crossing detection circuit according to Embodiment 1 of the present invention;

FIG. 4 is a schematic circuit diagram of a specific implementation of the principle diagram as shown in FIG. 3;

FIG. 5 is a principle diagram of a zero-crossing detection circuit according to Embodiment 2 of the present invention;

FIG. 6 is a schematic circuit diagram of a specific implementation of the principle diagram as shown in FIG. 5; and

FIG. 7 is a time sequence diagram of the zero-crossing detection circuit according to Embodiment 2 of the present invention.

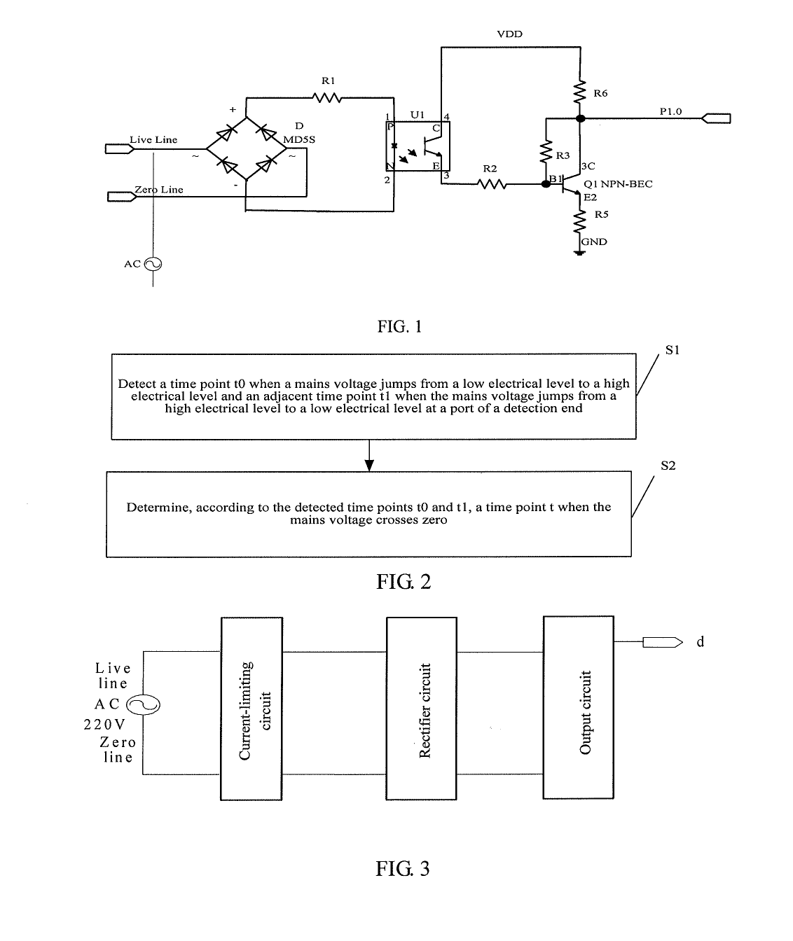

### DETAILED DESCRIPTION OF THE EMBODIMENTS

To solve the problem of high power consumption of the zero-crossing detection circuit in the prior art, the present invention provides a zero-crossing detection method and circuit, which are described in detail in the following with reference to the accompanying drawings and specific embodiments.

It is obvious that the described embodiments are merely a part rather than all of the embodiments of the present invention. All other embodiments obtained by persons of ordinary skill in the art based on the embodiments of the present invention without creative efforts shall fall within the protection scope of the present invention.

As shown in FIG. 2, an embodiment of the present invention provides a zero-crossing detection method, which includes:

S1: Detect a time point t0 when a mains voltage jumps from a low electrical level to a high electrical level and an adjacent time point t1 when the mains voltage jumps from a high electrical level to a low electrical level at a port of a detection end.

S2: Determine, according to the detected time points t0 and t1, a time point t when the mains voltage crosses zero.

In the zero-crossing detection method provided by the embodiment of the present invention, the time point when the mains voltage crosses zero is indirectly detected by detecting the time points t0 and t1 of two feature points when the mains voltage is approaching a peak value, and because a time period that the mains voltage is higher than the voltages at these two feature points when approaching the peak value is short, the zero-crossing detection method shortens the conduction time of a zero-crossing detection circuit, so that the power consumption is low.

In step S2, the determining, according to the detected time points t0 and t1, the time point t when the mains voltage crosses zero includes: t=t0+0.5(t1−t0)−5.

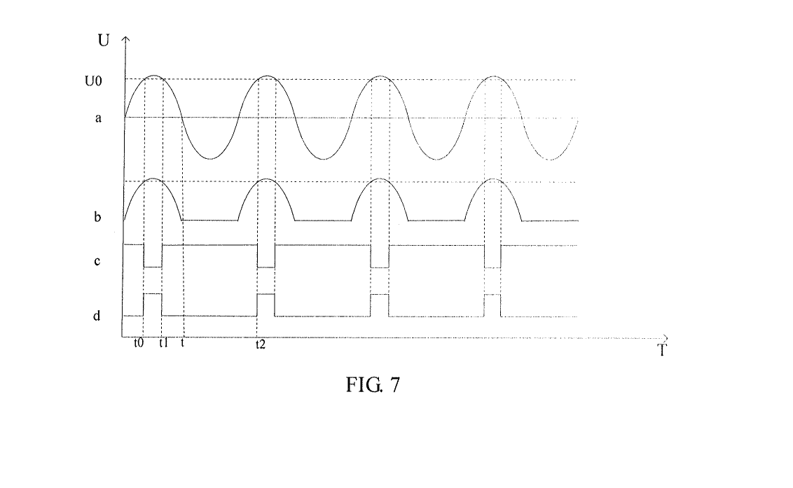

For example, as shown in FIG. 7, take the mains of 220 V in China as an example, and when a mains power source is powered on, a signal detected at a live line of the mains is a sine wave of 220 V, the t0 corresponds to a time point approaching a peak voltage in the sine wave, and the t1 corresponds to another time point approaching the peak voltage, in which the another time point is adjacent to the foregoing time point approaching the peak voltage, the t is the time point when the mains voltage crosses zero, and t2 differs by just one cycle from the t0.

Because the frequency of the mains is 50 Hz, according to the foregoing peak value detection principle, a cycle for producing a pulse signal is 20 ms, that is, t2−t0=20 ms in FIG. 7, and it is assumed that t1−t0=Δt, so that the finally calculated zero-crossing point is that t=(t0+0.5Δt−5) ms.

In addition, the present invention further provides an embodiment of a zero-crossing detection circuit, and the following takes the mains of 220 V in China as an example to illustrate the embodiment of the zero-crossing detection circuit in the present invention.

### Embodiment 1

Embodiment 1 of the present invention provides a schematic principle diagram of a zero-crossing detection circuit for implementing the foregoing zero-crossing detection method, and as shown in FIG. 3, the whole zero-crossing detection circuit includes a live line and a zero line of the mains, where the live line and the zero line of the mains are connected to a rectifier circuit, the rectifier circuit is connected to an output circuit, and a current-limiting circuit is connected between the live line and the zero line of the mains and the rectifier circuit.

Through the zero-crossing detection circuit provided by Embodiment 1 of the present invention, the current of the whole zero-crossing detection circuit is reduced to a great extent through a strong current-limiting function of the current-limiting circuit, so that the zero-crossing detection circuit is conducted when a mains voltage is approaching a peak value, the conduction time of the zero-crossing detection circuit is short and the power consumption is low.

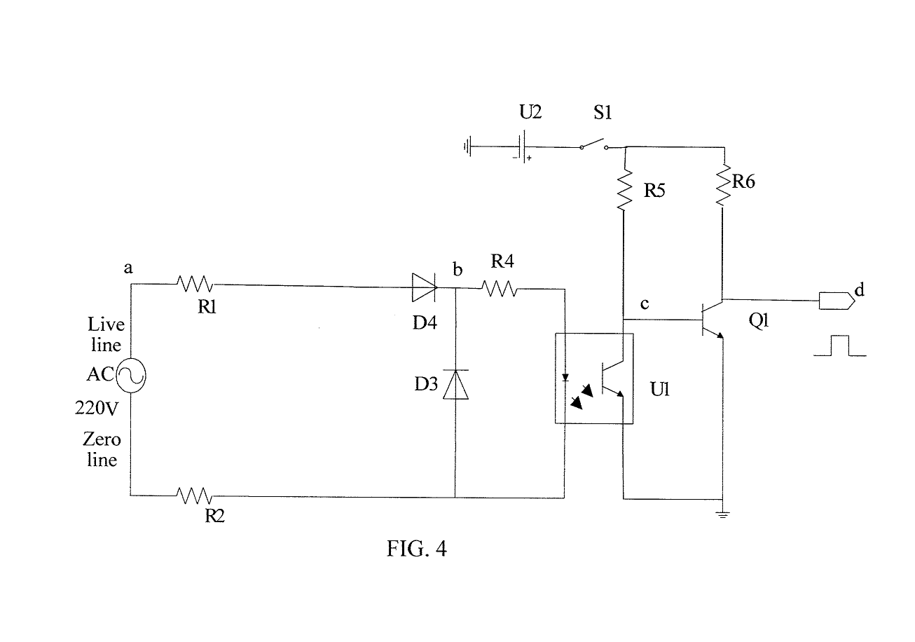

A schematic circuit diagram of a specific implementation of the zero-crossing detection circuit provided by Embodiment 1 of the present invention is shown in FIG. 4, and the zero-crossing detection circuit is specifically as follows: the current-limiting circuit includes a first current-limiting resistor R1 and a second current-limiting resistor R2, where the first current-limiting resistor R1 is connected in the live line, and the second current-limiting resistor R2 is connected in the zero line; the rectifier circuit is a half-bridge rectifier circuit, and the half-bridge rectifier circuit includes a first rectifier diode D3 and a second rectifier diode D4, where a positive pole of the first rectifier diode D3 is connected to the first current-limiting resistor R1 and a negative pole is connected to the output circuit through a protective resistor R4, and a positive pole of the second rectifier diode D4 is connected to the second current-limiting resistor R2 and a negative pole is connected to the output circuit through the protective resistor R4; the output circuit includes an optical coupler U1, a transistor Q1, a direct current power source U2, and a detection port, where a first input end of the optical coupler U1 is connected to the negative poles of the first rectifier diode D3 and the second rectifier diode D4 through the protective resistor R4, a second input end is connected to the positive pole of the second rectifier diode D4, a first output end is connected to a base of the transistor Q1, and a second output end is grounded; and the base of the transistor Q1 is connected to the first output end of the optical coupler U1 and connected to the direct current power source U2 through a first pull-up resistor R5, an emitter is grounded, and a collector is connected to the direct current power source U2 through a second pull-up resistor R6, where the detection port is guided from the collector of the transistor Q1.

When a mains power source is powered on, the half-bridge rectifier circuit rectifies a sine signal into a positive signal and blocks a negative signal. First, one half of the conduction time of the circuit is reduced, and when an input voltage of the optical coupler U1 is larger than a conduction voltage of the optical coupler U1, the optical coupler U1 is conducted, and a negative pulse signal is output at the detection port through a phase inversion function of the transistor Q1 Due to a strong current-limiting function of the first current-limiting resistor R1 and the second current-limiting resistor R2, the current in the circuit is reduced to a great extent, and in this way, the optical coupler U1 is conducted only when the mains voltage is approaching a peak value, so that the conduction time of the whole circuit is reduced to a great extent and the power consumption is low.

As an improvement to the foregoing embodiment, resistance values of the first current-limiting resistor R1 and the second current-limiting resistor R2 are larger than or equal to 300 kilo ohms, and the strong current-limiting function works for the zero-crossing detection circuit only when the current-limiting resistance is large.

Furthermore, the first current-limiting resistor R1 and the second current-limiting resistor R2 are adjustable resistors, Because the mains voltage has a certain offset, for example, in a condition that the power system of China is normal, a maximum offset allowed for a power supply voltage is +7% and −10% of a rated value, the resistance values of the first current-limiting resistor RI and the second current-limiting resistor R2 need to be modified to adjust a voltage value for outputting a negative pulse, so as to guarantee that the voltage value is in a variable range of the mains; and in addition, the resistance values of the first current-limiting resistor R1 and the second current-limiting resistor R2 may be modified to adjust a voltage value for outputting a negative pulse, so as to output the negative pulse signal when the mains voltage is most approaching a peak value.

Furthermore, the zero-crossing detection circuit of the foregoing embodiment further includes a switch S1. One end of the switch S1 is connected to the direct current power source U2 and the other end is connected to the first pull-up resistor R5 and the second pull-up resistor R6. The switch S1 is added and switched on only in outfield detection, so as to perform the zero-crossing detection, and in this way, the power consumption of the zero-crossing detection circuit is further lowered.

### Embodiment 2

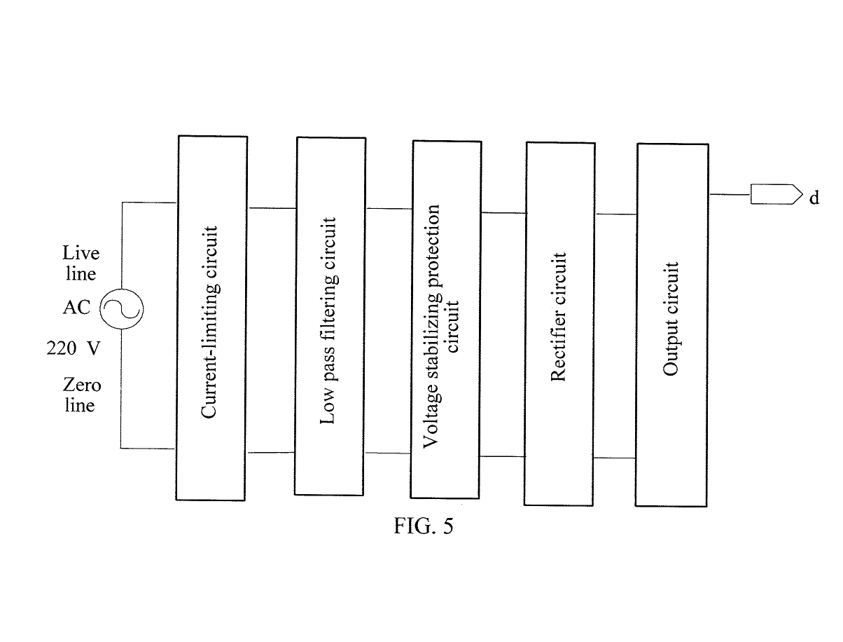

Embodiment 2 of the present invention provides another schematic principle diagram of a zero-crossing detection circuit for implementing the foregoing zero-crossing detection method. As shown in FIG. 5, different from Embodiment 1, the zero-crossing detection circuit in this embodiment further includes a low pass filtering circuit and a voltage stabilizing protection circuit, where the low pass filtering circuit is connected between the current-limiting circuit and the rectifier circuit, and the voltage stabilizing protection circuit is connected between the low pass filtering circuit and the rectifier circuit.

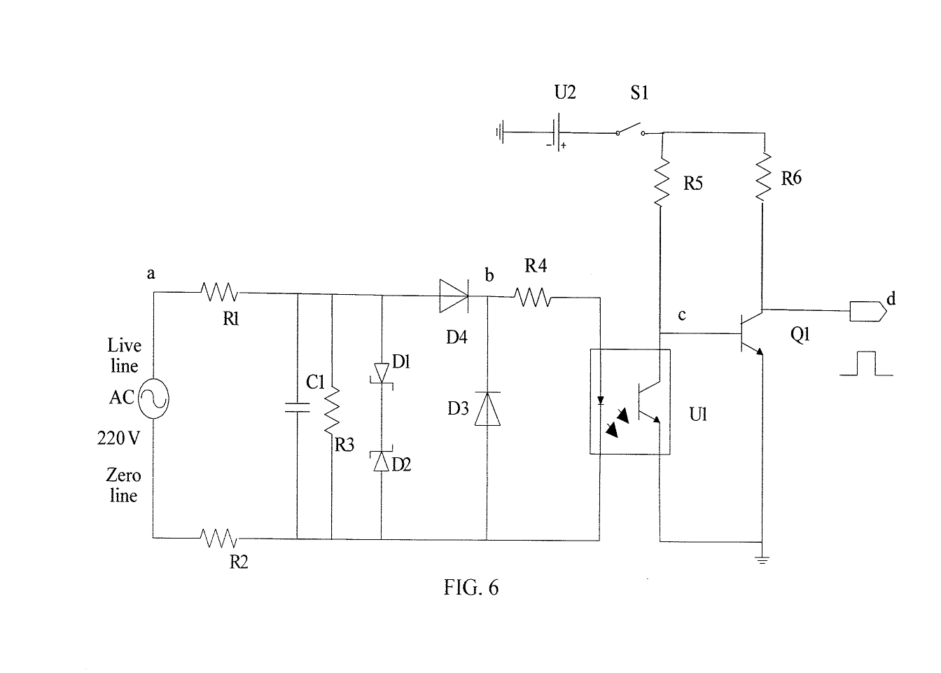

A schematic circuit diagram of a specific implementation of the zero-crossing detection circuit provided by Embodiment 2 of the present invention is shown in FIG. 6, and different from the specific implementation of the circuit in Embodiment 1, the circuit as shown in FIG. 6 specifically further includes an RC low pass filtering circuit composed of a resistor R3 and a capacitor C1 that are connected in parallel and a voltage stabilizing protection circuit composed of a first voltage stabilizing diode DI and a second voltage stabilizing diode D2 that are serially connected, where one end of the resistor R3 and one end of the capacitor C1 both are connected to the first current-limiting resistor R1 and the other end of the resistor R3 and the other end of the capacitor C1 both are connected to the second current-limiting resistor R2; a positive pole of the first voltage stabilizing diode D1 is connected to the first current-limiting resistor R1 and a negative pole is connected to a negative pole of the second voltage stabilizing diode D2, and a positive pole of the second voltage stabilizing diode D2 is connected to the second current-limiting resistor R2 and the negative pole is connected to the negative pole of the first voltage stabilizing diode D1.

In this embodiment, the low pass filtering circuit and the voltage stabilizing protection circuit are added based on Embodiment 1, where the RC low pass filtering circuit filters out a high frequency signal of the mains, and the voltage stabilizing protection circuit stabilizes a voltage applied on a rectifier bridge within a certain range. In this way, it is avoided that the detection circuit is wrongly triggered by a high-frequency high-voltage signal, and the zero-crossing detection circuit is more stable.

The zero-crossing detection method is specifically explained in the following with reference to Embodiment 1 and Embodiment 2:

FIG. 7 is a time sequence diagram of the zero-crossing detection circuit in Embodiment 2. It may be known with reference to FIG. 6 that, when the mains power source is powered on, a signal defected at a point a is a sine wave of 220 V, only a positive signal exists at a point b after half-bridge rectification, and when the optical coupler U1 is conducted, the voltage at a point c is pulled down, the optical coupler U1 outputs a negative pulse signal at the point c, and a positive pulse signal is finally output through phase inversion of Q1.

Because the frequency of the mains is 50 Hz, according to the foregoing peak value detection principle, a cycle for producing a pulse signal is 20 ms, that is, t2−t0=20 ms in FIG. 6; and according to the circuit as shown in FIG. 6, t1−t0=Δt of a pulse signal is finally obtained, a calculated voltage value for outputting a negative pulse is U0=220*sin ((5−0.5Δt)π/5), and finally a calculated zero-crossing point is t=(t0+0.5Δt−5) ms.

At the same time, the power consumption of this circuit is simply calculated as P=220*220/(R1+R2). When R1=R2=300 kilo ohms, the conduction time of the circuit which is saved by the switch S1 is excluded, and the power consumption is P=40.3 milliwatts, which has an obvious advantage compared with a zero-crossing detection circuit of the same kind.

In addition, according to a mains voltage standard of China, in a condition that the power system is normal, an offset allowed for the power supply frequency is ±0.5 Hz, and at the same time, according to the mains voltage standard of China, in a condition that the power system is normal, a maximum offset allowed for a power supply voltage is +7% and −10% of a rated value: therefore, the resistance values of the resistors R1 and R2 need to be modified to adjust a voltage value for outputting a negative pulse, so as to guarantee that the voltage value is in a variable range of the mains.

In Embodiment 2 of the present invention, the low pass filtering circuit and the voltage stabilizing protection circuit have a function of filtering out a high-frequency high-voltage signal of the mains, so as to make the zero-crossing detection more accurate.

The foregoing descriptions are merely specific embodiments of the present invention, but are not intended to limit the protection scope of the present invention. Any variation or replacement readily figured out by persons skilled in the art within the technical scope disclosed in the present invention shall fall within the protection scope of the present invention. Therefore, the protection scope of the present invention shall be defined according to the protection scope claimed by the claims.

What is claimed is:

1. A zero-crossing detection method, comprising:
detecting a time point t0 when a mains voltage jumps from a low electrical level to a high electrical level and an adjacent time point t1 when the mains voltage jumps from a high electrical level to a low electrical level at a port of a detection end; and
determining, according to the detected time points t0 and t1, a time point t when the mains voltage crosses zero.

2. The zero-crossing detection method according to claim 1, wherein the determining, according to the detected time points t0 and t1, the time point t when the mains voltage crosses zero comprises:
t=t0+0.5(t1−t0)−5.

3. A zero-crossing detection circuit for implementing the zero-crossing detection method according to claim 1, comprising a live line and a zero line of the mains, wherein the live line and the zero line of the mains are connected to a rectifier circuit, the rectifier circuit is connected to an output circuit, and a current-limiting circuit is connected between the live line and the zero line of the mains and the rectifier circuit.

4. The zero-crossing detection circuit according to claim 3, wherein the current-limiting circuit comprises a first current-limiting resistor and a second current-limiting resistor, the first current-limiting resistor is connected in the live line, and the second current-limiting resistor is connected in the zero line.

5. The zero-crossing detection circuit according to claim 4, wherein resistance values of the first current-limiting resistor and the second current-limiting resistor are larger than or equal to 300 kilo ohms.

6. The zero-crossing detection circuit according to claim 5, wherein the first current-limiting resistor and the second current-limiting resistor are adjustable resistors.

7. The zero-crossing detection circuit according to claim 4, wherein the rectifier circuit is a half-bridge rectifier circuit, and the half-bridge rectifier circuit comprises a first rectifier diode and a second rectifier diode,
a positive pole of the first rectifier diode is connected to the first current-limiting resistor, and a negative pole is connected to the output circuit through a protective resistor; and
a positive pole of the second rectifier diode is connected to the second current-limiting resistor, and a negative pole is connected to the output circuit through the protective resistor.

8. The zero-crossing detection circuit according to claim 7, wherein the output circuit comprises an optical coupler, a transistor, a direct current power source, and a detection port,
a first input end of the optical coupler is connected to the negative poles of the first rectifier diode and the second rectifier diode through the protective resistor, a second input end is connected to the positive pole of the second rectifier diode, a first output end is connected to a base of the transistor, and a second output end is grounded; and
the base of the transistor is connected to the first output end of the optical coupler and is connected to the direct current power source through a first pull-up resistor, an emitter is grounded, and a collector is connected to the direct current power source through a second pull-up resistor, wherein the detection port is guided from the collector of the transistor.

9. The zero-crossing detection circuit according to claim 8, further comprising a switch, wherein one end the switch is connected to the direct current power source, and the other end is connected to the first pull-up resistor and the second pull-up resistor.

10. The zero-crossing detection circuit according claim 4, further comprising a low pass filtering circuit, which is connected between the current-limiting circuit and the rectifier circuit,

11. The zero-crossing detection circuit according to claim 10, wherein the low pass filtering circuit is an RC low pass filtering circuit, and
the RC low pass filtering circuit comprises a resistor and a capacitor that are connected in parallel, and one end of the resistor and one end of the capacitor both are connected to the first current-limiting resistor, and the other end of the resistor and the other end of the capacitor both are connected to the second current-limiting resistor.

12. The zero-crossing detection circuit according to claim 11, further comprising a voltage stabilizing protection circuit, which is connected between the low pass filtering circuit and the rectifier circuit.

13. The zero-crossing detection circuit according to claim 12, wherein the voltage stabilizing protection circuit comprises a first voltage stabilizing diode and a second voltage stabilizing diode that are serially connected, a positive pole of the first voltage stabilizing diode is connected to the first current-limiting resistor, and a negative pole is connected to a negative pole of the second voltage stabilizing diode, and a positive pole of the second voltage stabilizing diode is connected to the second current-limiting resistor, and the negative pole is connected to the negative pole of the first voltage stabilizing diode.
